(19) United States
(12) Patent Application Publication
(10) Pub. No.: US 2008/0170640 A1
(43) Pub. Date: Jul. 17, 2008

(54) Methods and Apparatus For Hierarchical Modulation Using Radial Constellation

(75) Inventors: Wen Gao, Plainsboro, NJ (US); Joshua Lawrence Koslov, Hopewell, NJ (US); Kumar Ramaswamy, Princeton, NJ (US)

Correspondence Address: Joseph S.Tripoli;Patent Operations, P.O. Box 5312, Princeton, NJ, 08543-5312, US

(73) Assignee: THOMSON LICENSING, Boulogne-Billancourt (FR)

(21) Appl. No.: 10/567,946

(22) PCT Filed: Jul. 15, 2004
(86) PCT No.: PCT/US04/22780

§ 371 Date: Feb. 10, 2006

Related U.S. Application Data
(60) Provisional application No. 60/496,470, filed on Aug. 20, 2003.

(51) Int. Cl. H04L 27/34; H04L 27/12; H03C 3/00

(52) U.S. Cl. 375/302

(57) ABSTRACT

There is provided a method for hierarchical modulation relating to a first signal, a second signal, and an original constellation having a plurality of symbols in a non-uniform 8 Phase-Shift-Keying (PSK) configuration. Quadrature-Phase-Shift-Keying (QPSK) modulation is used for the first signal and Binary-Phase-Shift-Keying (BPSK) modulation is used for the second signal. The method includes the step of replacing at least some of the plurality of symbols with at least one radial-type QPSK-BPSK constellation.

### BACKGROUND OF THE INVENTION

The present invention generally relates to modulating radio frequency (RF) signals and, more particularly, to methods and apparatus for hierarchical modulation.

Hierarchical modulation is a modulation scheme wherein two signals with possibly different modulations are added together to generate a transmission signal. These two signals are referred to herein as the upper layer (UL) signal and the lower layer (LL) signal.

At the receiver, the received signal has a UL signal component and a LL signal component, i.e., the received signal is a combination of the upper and lower layers, and the receiver processes the received signal to recover therefrom the upper layer data (conveyed in the UL signal component) and the lower layer data (conveyed in the LL signal component). With respect to recovery of the upper layer data, the receiver simply demodulates and processes the received signal as if it were only composed of the UL signal component plus channel noise—in effect treating the LL signal component of the received signal as noise. Unfortunately, this extra noise may degrade the performance of the UL receiver.

### SUMMARY OF THE INVENTION

The problem stated above may be reduced, if not eliminated, by the present invention, which is directed to a method and apparatus for hierarchical modulation with a radial constellation.

According to an illustrative embodiment of the inventive concept, a hierarchical modulator employs a radial-type Quadrature Phase-Shift Keying-Binary Phase Shift Keying (QPSK-BPSK) constellation.

According to another embodiment of the inventive concept, there is provided a method for hierarchical modulation relating to a first signal and a second signal. In particular, the first signal is mapped to a QPSK symbol constellation and the second signal is mapped to a BPSK symbol constellation. The first and second signals are then combined such that the resulting symbol constellation is a radial-type QPSK-BPSK constellation.

According to another embodiment of the inventive concept, an apparatus for hierarchical modulation includes a mapping module for mapping a first signal and a second signal to symbols of a radial-type QPSK-BPSK constellation.

According to another embodiment of the inventive concept, a receiver includes a hierarchical demodulator that uses a radial-type constellation to recover the upper layer and lower layer signals.

According to yet another aspect of the present invention, there is provided a program storage device readable by machine, tangibly embodying a program of instructions executable by the machine to perform method steps for hierarchical modulation relating to a first signal and a second signal. In particular, the first signal is mapped to a QPSK symbol constellation and the second signal is mapped to a BPSK symbol constellation. The first and second signals are then combined such that the resulting symbol constellation is a radial-type QPSK-BPSK constellation.

These and other aspects, features and advantages of the present invention will become apparent from the following detailed description of preferred embodiments, which is to be read in connection with the accompanying drawings.

### BRIEF DESCRIPTION OF THE DRAWINGS

FIGS. 1 and 2 are diagrams illustrating a prior art hierarchical Quadrature Phase-Shift Keying-Binary Phase Shift Keying (QPSK-BPSK) constellation;

FIGS. 3 and 4 show an illustrative, radial-type hierarchical QPSK-BPSK constellation in accordance with the principles of the invention;

FIG. 5 shows an illustrative embodiment of a hierarchical modulator in accordance with the principles of the invention;

FIG. 6 shows an illustrative flow chart in accordance with the principles of the invention;

FIG. 7 shows another illustrative embodiment of a hierarchal modulator in accordance with the principles of the invention;

FIG. 8 shows an illustrative embodiment of a receiver in accordance with the principles of the invention;

FIGS. 9-11 are diagrams illustrating the bit error rate (BER) performance corresponding to various simulations; and

FIG. 12 shows another illustrative embodiment in accordance with the principles of the invention.

### DETAILED DESCRIPTION

Other than the inventive concept, the elements shown in the figures are well known and will not be described in detail. Also, familiarity with satellite-based systems is assumed and is not described in detail herein. For example, other than the inventive concept, satellite transponders, downlink signals, symbol constellations, a radio-frequency (rf) front-end, or receiver section, such as a low noise block down-converter, hierarchical modulator, hierarchical demodulator, formatting and source encoding methods (such as Moving Picture Expert Group (MPEG)-2 Systems Standard (ISO/IEC 13818-1)) for generating transport bit streams and decoding methods such as log-likelihood ratios, soft-input-soft-output (SISO) decoders, Viterbi decoders are well-known and not described herein. In addition, the inventive concept may be implemented using conventional programming techniques, which, as such, will not be described herein. Finally, like-numbers on the figures represent similar elements.

The present invention is directed to methods and apparatus for hierarchical modulation with radial-type constellations. It is to be understood that the present invention may be implemented in various forms of hardware, software, firmware, special purpose processors, or a combination thereof. Preferably, the present invention is implemented as a combination of hardware and software. Moreover, the software is preferably implemented as an application program tangibly embodied on a program storage device. The application program may be uploaded to, and executed by, a machine comprising any suitable architecture. Preferably, the machine is implemented on a computer platform having hardware such as one or more central processing units (CPU), a random access memory (RAM), and input/output (I/O) interface(s). The computer platform also includes an operating system and microinstruction code. The various processes and functions described herein may either be part of the microinstruction code or part of the application program (or a combination thereof) that is executed via the operating system. In addition, various other peripheral devices may be connected to the computer platform such as an additional data storage device and a printing device.

It is to be further understood that, because some of the constituent system components and method steps depicted in the accompanying figures are preferably implemented in software, the actual connections between the system components (or the process steps) may differ depending upon the manner in which the present invention is programmed. Given the teachings herein, one of ordinary skill in the related art will be able to contemplate these and similar implementations or configurations of the present invention.

Hierarchical modulation is a modulation scheme wherein two signals with possibly different modulations are added together to generate a signal for transmission. For illustration purposes, a specific kind of hierarchical modulation is described herein, wherein a constellation (e.g., a mini-constellation) replaces each symbol of an original QPSK constellation. This constellation may be, but is not limited to, Binary Phase-Shift Keying (BPSK). The original QPSK signal is referred to as the upper layer (UL) signal, and the signal that is carried by the mini-constellation(s) is referred to as the lower layer (LL) signal. It is to be appreciated that the present invention is not limited to solely the modulation and constellation types and arrangements shown and described herein and, thus, other modulation and constellation types and arrangements may also be utilized in accordance with the present invention, while maintaining the spirit of the present invention.

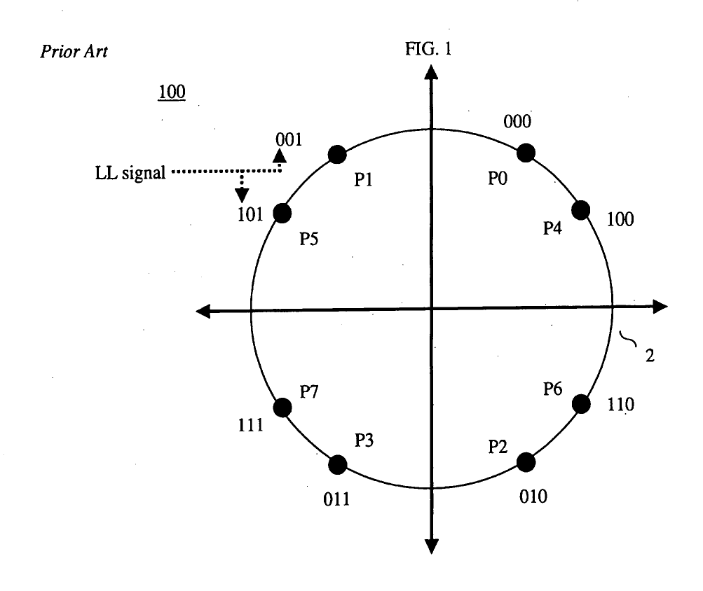

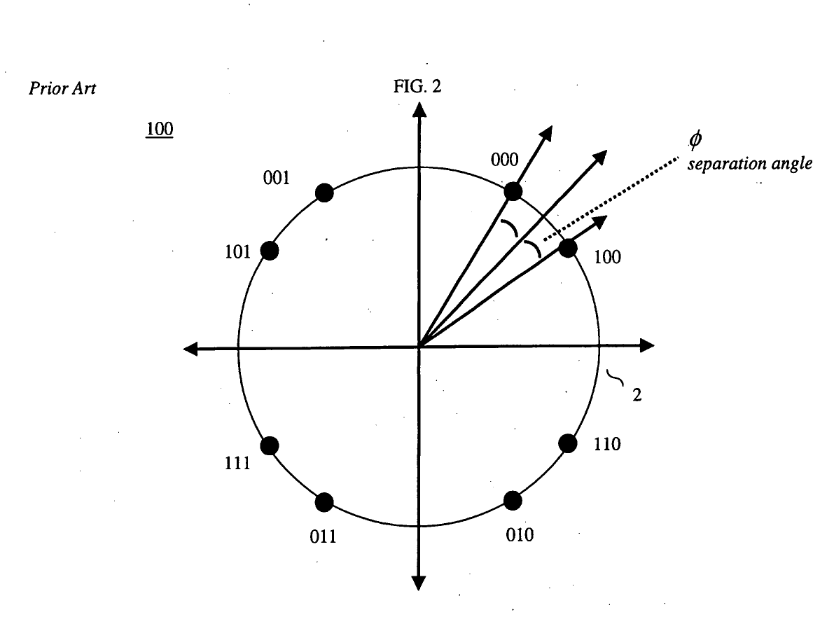

FIG. 1 is a diagram illustrating a prior art hierarchical Quadrature Phase-Shift Keying-Binary Phase Shift Keying (QPSK-BPSK) constellation 100. As can be observed from FIG. 1, constellation 100 is a non-uniform N-PSK constellation, where N is equal to 8, i.e., an 8-PSK constellation comprising eight symbols. Each symbol is located the same distance from the origin as represented by their location on a circumference of circle 2 and each symbol is associated with a predefined bit pattern. For example, the symbol P5 is associated with the bit pattern 101. As can also be observed from FIG. 1, the left-most bit represents the LL signal. As such, the LL signal is transmitted via each of the “mini-constellations” in each quadrant of constellation 100. For example, reception by a receiver of a signal point in quadrant four (symbols P1 or P5) conveys the bits “01” of the UL signal; while the bits conveyed by the LL signal require the receiver to determine whether the received signal point was symbol P1 or symbol P5. Constellation 100 is a non-uniform constellation since the separation angle, 2φ, (between adjacent symbols in the symbol space) is not equal to 45° (360°/N). The definition of separation angle is further illustrated in FIG. 2.

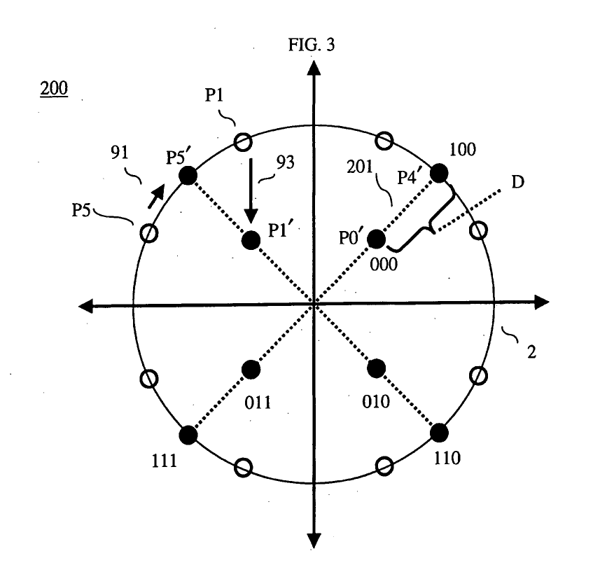

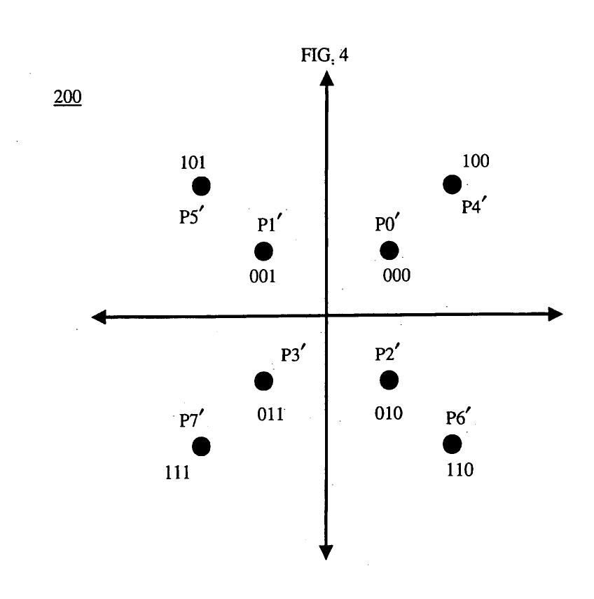

Turning now to FIG. 3, and in accordance with the principles of the invention, an illustrative radial-type hierarchical QPSK-BPSK constellation 200 is shown. As can be observed from FIG. 3, the eight symbols of the prior 8-PSK constellation are re-arranged, i.e., re-mapped, in the symbol space. In particular, the “open circles” represent the prior positions of the symbols of the 8PSK hierarchical constellation (e.g., of FIG. 1); while the “filled circles” represent the new positions of the symbols in the constellation space in accordance with the principles of the invention. This is further illustrated by the “open circle” symbol P5, which has been moved in the symbol space in the direction of arrow 91 to the position of symbol P5′ (filled circle). Likewise for the “open circle” symbol P1, which has been moved in the symbol space in the direction of arrow 93 to the position of symbol P1′ (filled circle). As such, and as can be observed from FIG. 3, in each quadrant each pair of symbols lies on the same radial of the circle 2. For example, the pair of symbols P0′ and P4′ lie on radial 201 and are separated by a distance, D. Illustratively, this separation distance, D, is equal for all pairs in each quadrant. In accordance with a feature of the invention, the separation distance, D, can be varied to alter system performance. As used herein, the phrase “radial-type QPSK-BPSK constellation” refers to a constellation of symbols of the type illustrated in FIG. 3. Further, the term “radial symbol” refers to a symbol not lying on the circumference of the circle but lying on a radial, and the term “circumference symbol” refers to a symbol lying on the circumference of the circle (not necessarily lying on a radial). In this context, and as can be observed from FIG. 3, circumference symbol P4′ and radial symbol P0′ lie on radial 201. Turning briefly to FIG. 4, the latter illustrates another view of the radial-type constellation previously shown in FIG. 3 without the clutter of circle 2, etc.

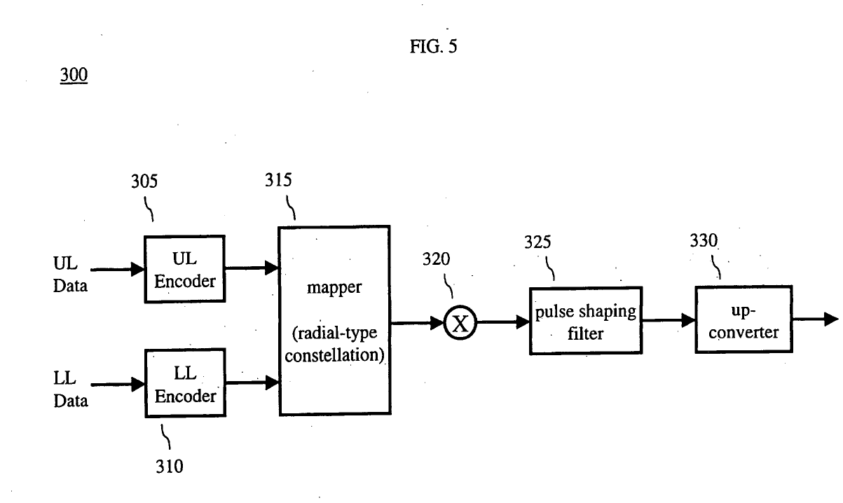

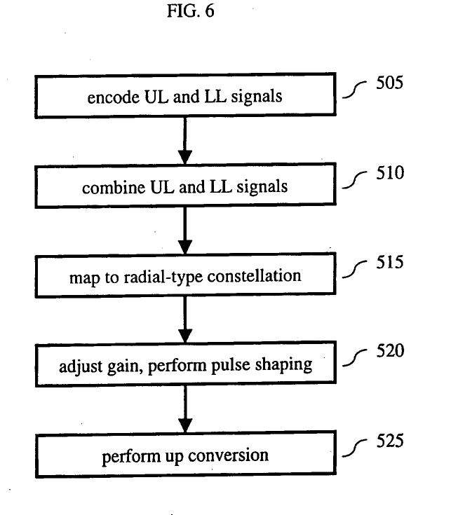

Referring now to FIG. 5, an illustrative embodiment of a transmitter 300 in accordance with the principles of the invention is shown. The transmitter 300 of FIG. 5 comprises a UL encoder 305, a LL encoder 310, a mapper 315 (also referred to herein as a “mapping module”), multiplier 320, pulse shaping filter 325 and up-converter 330. Reference at this time can also be made to FIG. 6, which shows an illustrative flow chart for use in a transmitter in accordance with the principles of the invention.

UL data and LL data are input to UL encoder 305 and LL encoder 310, respectively, for encoding (step 505 of FIG. 6). It is to be appreciated that in another embodiment of the present invention, the UL and LL data may be input to a single encoder. Then, the UL and LL encoded sequences are combined (step 510 of FIG. 6), where two bits from the UL encoded sequence and one bit from the LL encoded sequence are used as an input to mapper 315. The mapper 315 maps the combined UL and LL sequence to a radial-type constellation, and then outputs the corresponding constellation symbol (step 515 of FIG. 6). The constellation used in mapper 315 is illustratively the radial-type constellation shown in FIGS. 3 and 4.

The magnitude of the signal from mapper 315 is adjusted by multiplier 320 and pulse shaped by pulse shaping filter 325 (step 520 of FIG. 6). The resulting signal is applied to up-converter 330 for up-conversion for transmission, e.g., via a satellite transmitting antenna (not shown) (step 525 of FIG. 6).

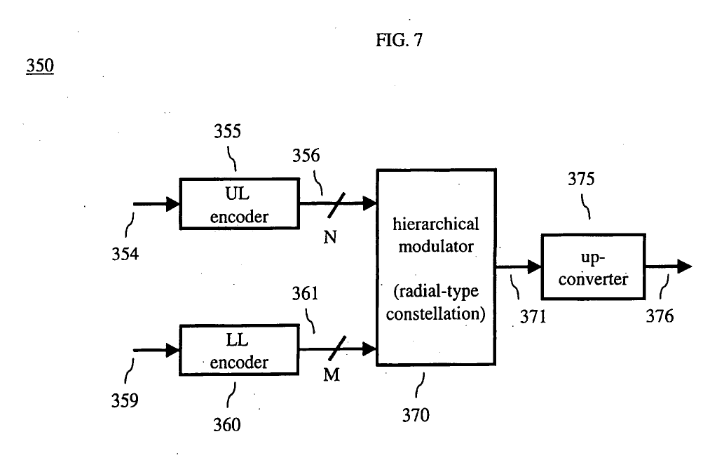

Another view of a transmitter in accordance with the principles of the invention is shown in FIG. 7. Transmitter 350 comprises UL encoder 355, LL encoder 360, hierarchical modulator 370 and up-converter 375. A UL signal 354 is applied to UL encoder 355, which encodes the signal and provides encoded signal 356 having N bits of data (e.g., N=2) each signaling interval, T. Similarly, a LL signal 359 is applied to LL encoder 360, which encodes the signal and provides encoded signal 361 having M bits of data (e.g., M=1) each signal interval, T. The encoded signals 356 and 361 are applied to hierarchical modulator 370. The latter, in accordance with the principles of the invention, maps the encoded signals each signaling interval to symbols selected from a radial-type constellation (e.g., as illustrated in FIGS. 3 and 4). For example, each signaling interval hierarchical modulator 370 maps (2+1) bits to select one of the symbols from the constellation of symbols {P0, P1, P2, P3, P4, P5, P6 and P7} shown in FIG. 3. The resulting signal 371 (which may be further processed, e.g., the above-mentioned gain adjustment and pulse shaping) is applied to up-converter 375 for transmission.

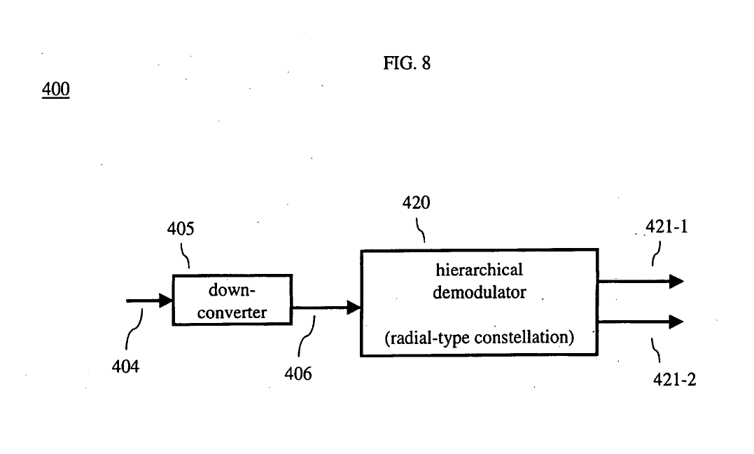

Turning now to FIG. 8, an illustrative embodiment of a receiver 400 in accordance with the principles of the invention is shown. Receiver 400 comprises down-converter 405 and hierarchical demodulator 420. A received signal 404 (e.g., from a satellite antenna (not shown) is applied to down-converter 405, which provides signal 406 to hierarchical demodulator 420. The latter, in accordance with the principles of the invention, uses a radial-type constellation (e.g., as illustrated in FIGS. 3 and 4) for recovery of the UL signal and LL signal, as represented by signals 421-1 and 421-2, respectively.

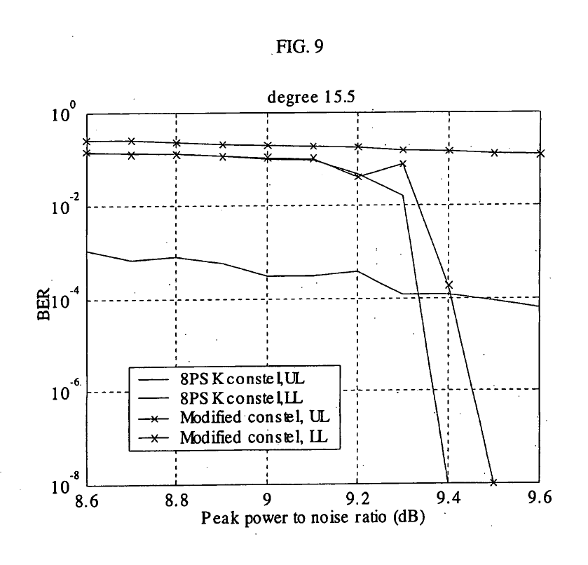

Illustrative simulation results comparing the illustrative radial-type constellation of FIGS. 3 and 4 to the prior art QPSK-BPSK constellation of FIGS. 1 and 2 for different separation angles are shown in FIGS. 9-11.

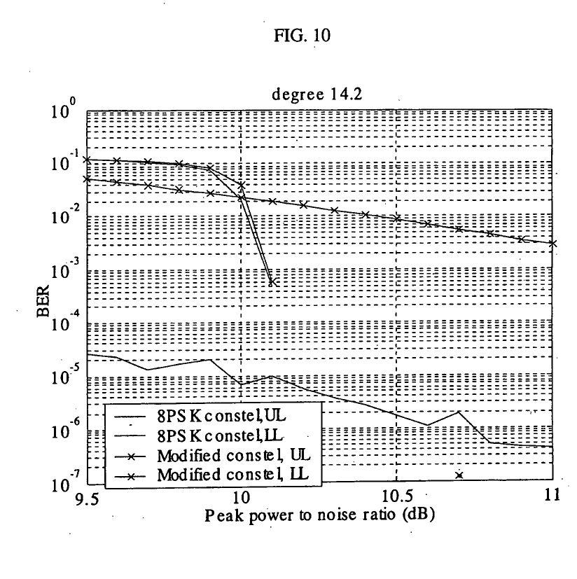

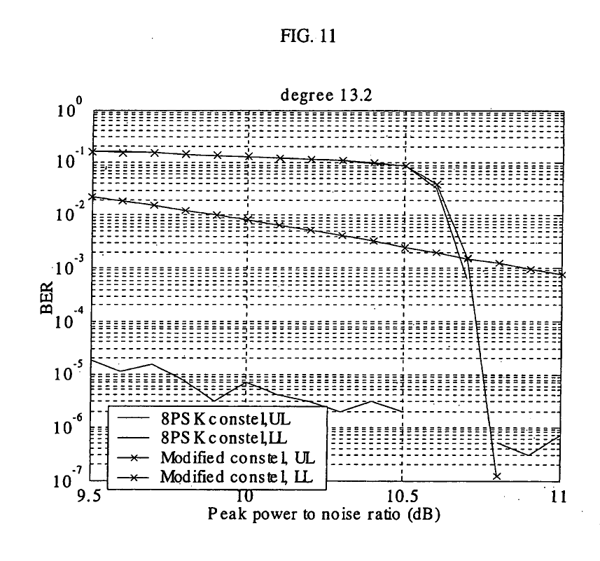

The simulations involve hierarchical QPSK-BPSK, with non-uniform 8PSK constellations having 15.5° (FIG. 9), 14.2° (FIG. 10), and 13.2° (FIG. 11) separation angles and the corresponding modified radial-type QPSK-BPSK constellation shown in FIGS. 3 and 4. For comparison, it is assumed that the distance between a constellation point pair in one quadrant is the same for both constellations. The channel impairment is Gaussian noise only. The upper layer uses a rate 6/7 convolutional code and the lower layer uses a rate 1/2 LDPC (low density parity check) code that is defined in the Second Generation Digital Video Broadcast Standard (DVB-S2). The BER (bit error rate) requirement is that the upper layer BER is less than 1.8*10⁻³ and the lower layer BER is less than 10⁻⁷.

In accordance with a feature of the invention, a radial-type constellation facilitates carrier recovery, while carrier recovery in a non-uniform 8PSK of the prior art is affected by the separation angle between the two constellation points within one quadrant. On the other hand, the radial-type constellation limits the performance of the upper layer, which may result in a higher PSNR (peak symbol energy to noise ratio) to satisfy both the upper and lower layer BER requirements. It should be noted that when an existing legacy receiver sets a limit on the separation angle, the radial-type constellation may be used to reduce the PSNR requirement. For example, if a legacy receiver requires that the separation angle be less than or equal to 12.0 degrees, then the radial type constellation that corresponds to a 13.2 degree non-uniform 8PSK constellation can be used to reduce the system PSNR requirement.

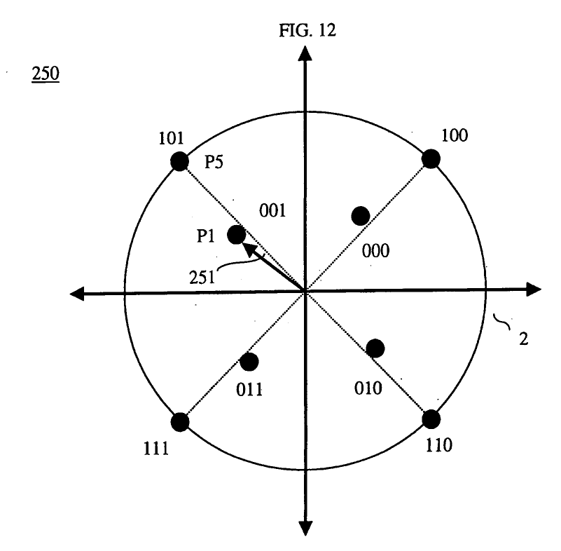

FIG. 12 is another illustrative embodiment in accordance with the principles of the invention. In FIG. 12, the radial-type constellation 250 comprises internal symbols that lie substantially along the respective radial that intersects a symbol lying on the circumference of the circle. For example, the symbol P1 is offset by a small angle 251 from the radial intersecting symbol P5.

Although the illustrative embodiments have been described herein with reference to the accompanying drawings, it is to be understood that the present invention is not limited to those precise embodiments, and that various other changes and modifications may be affected therein by one of ordinary skill in the related art without departing from the scope or spirit of the invention. All such changes and modifications are intended to be included within the scope of the invention as defined by the appended claims.

1. A method for use in hierarchical modulation, the method comprising:
hierarchically modulating at least a first signal and a second signal to provide a hierarchical modulation signal; and
transmitting the hierarchical modulation signal;
wherein the hierarchical modulation signal comprises a sequence of symbols selected from a radial-type constellation of symbols.

2. The method of claim 1, wherein the transmitting step includes the step of up-converting the hierarchical modulation signal to a radio frequency for transmission.

3. The method of claim 1, wherein the radial-type constellation of symbols comprises a number of symbols arranged in a signal space comprising four quadrants, wherein the symbols in a quadrant are arranged such that for every symbol lying on a circumference of a circle at least one other symbol lies on a radial of the circle such that the radial also intersects the symbol on the circumference.

4. The method of claim 3, wherein the hierarchically modulating step includes the step of adjusting a separation distance, D, between a circumference symbol and a radial symbol.

5. The method of claim 1, wherein the radial-type constellation of symbols comprises a number of symbols arranged in a signal space comprising four quadrants, wherein the symbols in a quadrant are arranged such that for every symbol lying on a circumference of a circle at least one other symbol lies substantially on a radial of the circle such that the radial also intersects the symbol on the circumference.

6. The method of claim 5, wherein the hierarchically modulating step includes the step of adjusting a separation distance, D, between a circumference symbol and a radial symbol.

7. A method for use in hierarchical modulation, the method comprising:
using a quadrature phase shift keying (QPSK) symbol constellation for an upper layer signal;
using a binary phase shift keying (BPSK) symbol constellation for a lower layer signal; and
hierarchically modulating the upper layer signal and the lower layer signal for providing a sequence of symbols for transmission;
wherein, the hierarchically modulating step combines the QPSK symbol constellation and the BPSK symbol constellation such that the sequence of symbols are selected from a radial-type QPSK-BPSK constellation of symbols.

8. A method for use in hierarchical modulation, the method comprising:
encoding an upper layer (UL) signal to provide an encoded UL signal;
encoding a lower layer (LL) signal to provide an encoded LL signal; and
mapping the encoded UL signal and the encoded LL signal to a radial-type symbol constellation to provide a sequence of symbols for transmission;
wherein the radial-type constellation of symbols comprises a number of symbols arranged in a signal space comprising four quadrants, wherein the symbols in a quadrant are arranged such that for every symbol lying on a circumference of a circle at least one other symbol lies on a radial of the circle such that the radial also intersects the symbol on the circumference.

9. A method for use in hierarchical modulation, the method comprising:
encoding an upper layer (UL) signal to provide an encoded UL signal;
encoding a lower layer (LL) signal to provide an encoded LL signal; and
mapping the encoded UL signal and the encoded LL signal to a radial-type symbol constellation to provide a sequence of symbols for transmission;
wherein the radial-type constellation of symbols comprises a number of symbols arranged in a signal space comprising four quadrants, wherein the symbols in a quadrant are arranged such that for every symbol lying on a circumference of a circle at least one other symbol lies substantially on a radial of the circle such that the radial also intersects the symbol on the circumference.

10. Apparatus for use in hierarchical modulation, the apparatus comprising:
a hierarchical modulator for modulating at least a first signal and a second signal to provide a hierarchical modulation signal;
wherein the hierarchical modulation signal comprises a sequence of symbols selected from a radial-type constellation of symbols.

11. The apparatus of claim 10, further comprising an up-converter for transmitting the hierarchical modulation signal.

12. The apparatus of claim 10, wherein the radial-type constellation of symbols comprises a number of symbols arranged in a signal space comprising four quadrants, wherein the symbols in a quadrant are arranged such that for every symbol lying on a circumference of a circle at least one other symbol lies on a radial of the circle such that the radial also intersects the symbol on the circumference.

13. The apparatus of claim 12, wherein the hierarchical modulator adjusts a separation distance, D, between a circumference symbol and a radial symbol.

14. The apparatus of claim 10, wherein the radial-type constellation of symbols comprises a number of symbols arranged in a signal space comprising four quadrants, wherein the symbols in a quadrant are arranged such that for every symbol lying on a circumference of a circle at least one other symbol lies substantially on a radial of the circle such that the radial also intersects the symbol on the circumference.

15. The apparatus of claim 14, wherein the hierarchical modulator adjusts a separation distance, D, between a circumference symbol and a radial symbol.

16. Apparatus for use in hierarchical modulation, the apparatus comprising:
an upper level (UL) encoder for providing a UL encoded signal;
a lower level (LL) encoder for providing a LL encoded signal; and
a hierarchical modulator responsive to the UL encoded signal and the LL encoded signal for providing a sequence of symbols for transmission;
wherein the hierarchical modulator selects the symbols from a radial-type signal constellation that is a combination of a quadrature phase shift keying (QPSK) symbol constellation and a binary phase shift keying (BPSK) symbol constellation.

17. Apparatus for use in a receiver, the apparatus comprising:
a down-converter for providing a received signal; and
a hierarchical demodulator that processes the received signal by using a radial-type constellation of symbols for recovery of upper layer (UL) data and lower layer (LL) data.

18. The apparatus of claim 17, wherein the radial-type constellation of symbols is a combination of a quadrature phase shift keying (QPSK) symbol constellation and a binary phase shift keying (BPSK) symbol constellation.

19. The apparatus of claim 17, wherein the radial-type constellation of symbols comprises a number of symbols arranged in a signal space comprising four quadrants, wherein the symbols in a quadrant are arranged such that for every symbol lying on a circumference of a circle at least one other symbol lies on a radial of the circle such that the radial also intersects the symbol on the circumference.

20. The apparatus of claim 17, wherein the radial-type constellation of symbols comprises a number of symbols arranged in a signal space comprising four quadrants, wherein the symbols in a quadrant are arranged such that for every symbol lying on a circumference of a circle at least one other symbol lies substantially on a radial of the circle such that the radial also intersects the symbol on the circumference.

21. Apparatus for use in a receiver, the apparatus comprising:
a down-converter for providing a received signal; and
a hierarchical demodulator for processing the received signal for recovering upper layer (UL) data and lower layer (LL) data;
wherein the received signal represents a sequence of symbols selected from a radial-type constellation of symbols.

22. The apparatus of claim 21, wherein the radial-type constellation of symbols comprises a number of symbols arranged in a signal space comprising four quadrants, wherein the symbols in a quadrant are arranged such that for every symbol lying on a circumference of a circle at least one other symbol lies on a radial of the circle such that the radial also intersects the symbol on the circumference.

23. The apparatus of claim 21, wherein the radial-type constellation of symbols comprises a number of symbols arranged in a signal space comprising four quadrants, wherein the symbols in a quadrant are arranged such that for every symbol lying on a circumference of a circle at least one other symbol lies substantially on a radial of the circle such that the radial also intersects the symbol on the circumference.

24. A program storage device readable by machine, tangibly embodying a program of instructions executable by the machine to perform method steps for hierarchical modulation, the steps comprising:
using a quadrature phase shift keying (QPSK) symbol constellation for an upper layer signal;
using a binary phase shift keying (BPSK) symbol constellation for a lower layer signal; and
hierarchically modulating the upper layer signal and the lower layer signal for providing a sequence of symbols for transmission;
wherein, the hierarchically modulating step combines the QPSK symbol constellation and the BPSK symbol constellation such that the sequence of symbols are selected from a radial-type QPSK-BPSK constellation of symbols.
